(19) United States
(12) Patent Application Publication
(10) Pub. No.: US 2023/0006117 A1
(43) Pub. Date: Jan. 5, 2023

(54) ELECTRONIC PART AND METHOD OF PRODUCING ELECTRONIC PART

(71) Applicant: SONY GROUP CORPORATION, TOKYO (JP)

(72) Inventors: JUN SUZUKI, TOKYO (JP); TAKESHI MIZUNO, TOKYO (JP)

(21) Appl. No.: 17/756,476

(22) PCT Filed: Nov. 13, 2020
(86) PCT No.: PCT/JP2020/042373

§ 371 Date: May 25, 2022

(30) Foreign Application Priority Data
Dec. 3, 2019 (JP) 2019-218634

(51) Int. Cl. H01L 33/62; H01L 21/66; H01L 33/52

(52) U.S. Cl. CPC H01L 33/62; H01L 22/20; H01L 33/52; H01L 2933/0066; H01L 2933/005

(57) ABSTRACT

An electronic part includes: a chip part having a first main surface and a second main surface opposite to the first main surface, a wiring portion being derived from the chip part; and a substrate having a pad forming surface, pads to which the wiring portion can be connected being formed on the pad forming surface, in which a gap is formed between the second main surface and the pad forming surface while the wiring portion is connected to a predetermined pad of the pads.

### TECHNICAL FIELD

The present disclosure relates to an electronic part and a method of producing an electronic part.

### BACKGROUND ART

In the past, a technology for mounting a chip part such as a semiconductor chip and an LED (Light Emitting Diode) chip on a substrate has been proposed. As the method of electrically connecting a chip part to a substrate, wire bonding connection, NCF bonding using an NCF (Non Conductive Film), ultrasonic bonding, solder bonding, and the like have been known. For example, the following Patent Literature 1 describes a technology for connecting an LED chip to a substrate by wire bonding connection.

### CITATION LIST

### Patent Literature

Patent Literature 1: Japanese Patent Application Laid-open No. 2006-108411

### DISCLOSURE OF INVENTION

### Technical Problem

Incidentally, for example, in the case where a chip part connected to a substrate is defective and electrical conduction cannot be achieved, it is necessary to perform an operation of removing the chip part from the substrate and newly connecting a normal chip part to the substrate (referred to also as repair). However, since the above-mentioned wire bonding connection, NCF bonding, and ultrasonic bonding are irreversible connection methods, a chip part once connected to a substrate cannot be easily removed. If a physical force is applied to a chip part to mechanically remove the chip part in order to remove the chip part from the substrate, there is a possibility that the substrate side is damaged. For this reason, there is a problem that the repair yield is reduced. Further, in the case of solder bonding, a chip part can be removed by reheating the solder to melt the solder. However, since the solder remains on the substrate even after the chip is removed, there is a possibility that the remaining solder deteriorates the repair yield. Further, there is a possibility that the heat during solder bonding is repeatedly applied to the substrate, resulting in a damage to the substrate.

It is an object of the present disclosure to provide an electronic part and a method of producing an electronic part that facilitate the removal of a chip part connected to a substrate.

### Solution to Problem

The present disclosure is, for example, an electronic part, including:

a chip part having a first main surface and a second main surface opposite to the first main surface, a wiring portion being derived from the chip part; and

a substrate having a pad forming surface, pads to which the wiring portion can be connected being formed on the pad forming surface, in which

a gap is formed between the second main surface and the pad forming surface while the wiring portion is connected to a predetermined pad of the pads.

The present disclosure is, for example, a method of producing an electronic part, including:

connecting a wiring portion to a predetermined pad formed on a pad forming surface of a substrate, the wiring portion being derived from a chip part having a first main surface and a second main surface opposite to the first main surface;

performing an electrical inspection while the wiring portion is connected to the pad; and

sealing, where a result of the inspection is OK, a part including the chip part and the wiring portion with a resin, and cutting, where a result of the inspection is NG, the wiring portion by applying a weight to the first main surface of the chip part.

### BRIEF DESCRIPTION OF DRAWINGS

FIG. 1 is a side view of a chip part according to a first embodiment.

Part A of FIG. 2 is a top view of a wiring portion according to the first embodiment, and Part B of FIG. 2 is a side view of the wiring portion according to the first embodiment.

FIG. 3 is a top view of a substrate according to the first embodiment.

Part A of FIG. 4 is a top view of a state where the chip part according to the first embodiment is connected to the substrate, and Part B of FIG. 4 is a diagram showing the cross section in the case where a part including the chip part and the substrate according to the first embodiment is cut by a predetermined cutting line.

FIG. 5 is a diagram schematically showing a state where the chip part according to the first embodiment is sealed with a resin.

Part A of FIG. 6 and Part B of FIG. 6 are each a diagram describing an example of processing of removing the chip part in processing relating to repair.

FIG. 7 is a side view of a chip part according to a second embodiment.

Part A of FIG. 8 and Part B of FIG. 8 are each a diagram referred to when a recessed portion according to the second embodiment is described.

Part A of FIG. 9 and Part B of FIG. 9 are each a diagram describing a modified example.

FIG. 10 is a diagram describing a modified example.

FIG. 11 is a diagram describing a modified example.

FIG. 12 is a diagram describing a modified example.

Part A of FIG. 13 to Part C of FIG. 13 are each a diagram describing a modified example.

### MODE(S) FOR CARRYING OUT THE INVENTION

Hereinafter, embodiments of the present disclosure will be described with reference to the drawings. Note that description will be made in the following order.

<Problems to be considered in present disclosure>

<First embodiment>

<Second embodiment>

<Modified example>

The embodiments and the like described below are suitable specific examples of the present disclosure, and the content of the present disclosure is not limited to these embodiments and the like.

### Problems to be Considered in Present Disclosure

First, in order to facilitate the understanding of the present disclosure, problems to be considered in the present disclosure will be described.

For example, in the technology described in Patent Literature 1, since a chip part is connected on a conductive pattern via a conductive adhesive, the chip part is already completely fixed to a substrate at the state of conducting an electrical inspection (test) such as one regarding whether or not electrical conduction is normal. For this reason, in the case where the result of the inspection is abnormal (NG), there is a high possibility that the substrate is damaged because it is necessary to peel the adhesive for repairing. Therefore, it is desirable that the chip part is not completely fixed to the substrate at the stage of an electrical inspection. Meanwhile, in the case where the electrical inspection is normal, it is desirable that the chip part is stably fixed to the substrate.

Further, in a generally known QFP (Quad Flat Package) package, there is an element in the package and the element is connected to a lead frame via wire bonding to make electrical connection. The size of the chip part increases because it is packaged, and thus, it is desirable that the wiring for making electrical connection is derived from the element itself. Embodiments of the present disclosure made in view of the above viewpoint will be described in detail.

### First Embodiment

[Configuration Example of Chip Part]

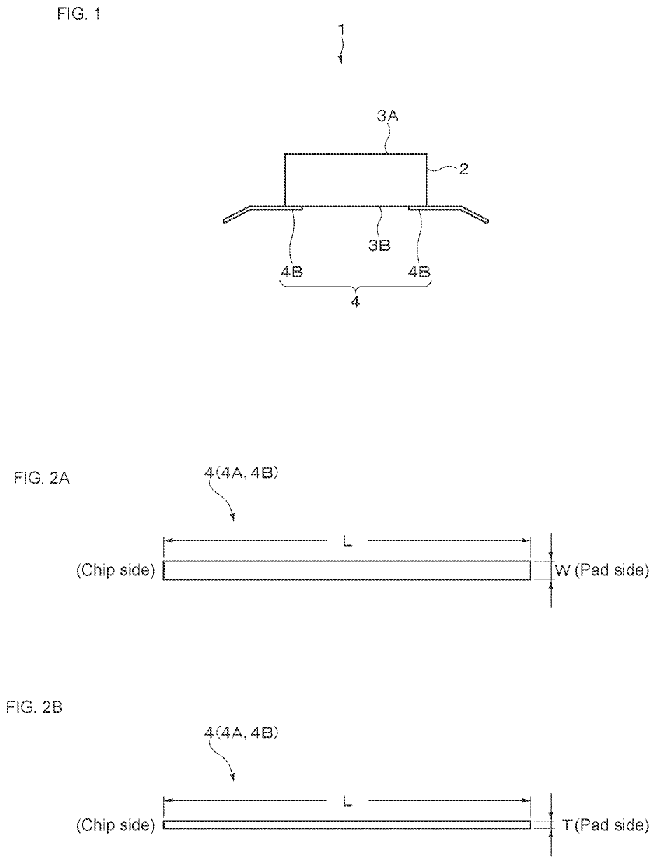

FIG. 1 is a side view of a chip part (chip part 1) according to a first embodiment. The chip part 1 includes a chip body portion 2. The chip body portion 2 includes, for example, an LED (Light Emitting Diode) that is an example of a light-emitting element. The shape of the chip body portion 2 is, for example, a rectangular parallelepiped shape having a length, a width, and a height of approximately several mm. The shape of the chip body portion 2 may be any shape such as a columnar shape and prismatic shape. The chip body portion 2 has an upper surface 3A that is an example of a first main surface and a bottom surface 3B that is an example of a second main surface.

A wiring portion 4 is derived (pulled out) from the chip body portion 2. As shown in FIG. 1, the wiring portion 4 includes a wiring 4A and a wiring 4B as a plurality of wirings. The wiring 4A is a wiring on an anode side, and the wiring 4B is a wiring on a cathode side. It goes without saying that they may be replaced with each other. The part where the wiring 4A and the wiring 4B are derived can be an appropriate part. Note that in the following description, in the case where it is unnecessary to particularly distinguish the wiring 4A and the wiring 4B from each other, they are collectively referred to as the wiring portion 4 as appropriate. As shown in FIG. 1, the wiring portion 4 is bent downward from the middle thereof, and the tip of the wiring portion 4 is connected to a pad (referred to also as a land) of a substrate described below.

Part A of FIG. 2 is a top view of the wiring portion 4, and Part B of FIG. 2 is a side view of the wiring portion 4. The wiring portion 4 is, for example, a thin plate-shaped foil having a rectangular shape in a top view. In the following description, description will be made with the size of the wiring portion 4 in the longitudinal direction as the length L of the wiring portion 4, the size of the wiring portion 4 in the lateral direction as the width W of the wiring portion 4, and the thickness of the wiring portion 4 as the thickness T of the wiring portion 4. For example, the length L of the wiring portion 4 is approximately 1 μm to 1000 μm, the width W of the wiring portion 4 is approximately 1 μm to 100 μm, and the thickness T of the wiring portion 4 is approximately several microns.

The wiring portion 4 is formed by an appropriate technology for forming a wiring, such as a sputtering method, plating, and vapor deposition. The wiring portion 4 is formed of a conductive material, i.e., aluminum (Al), copper (Cu), tungsten (W), titanium (Ti), gold(Au), an alloy thereof, or the like.

[Configuration Example of Substrate]

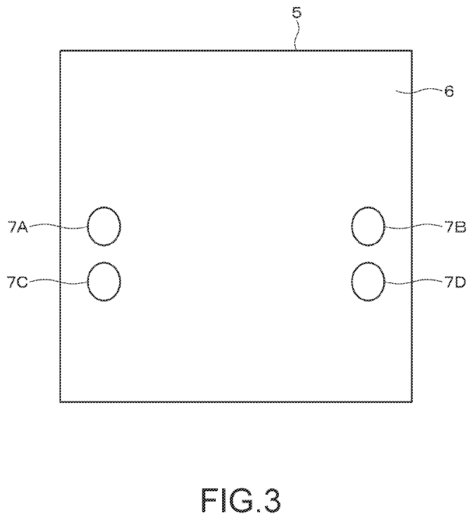

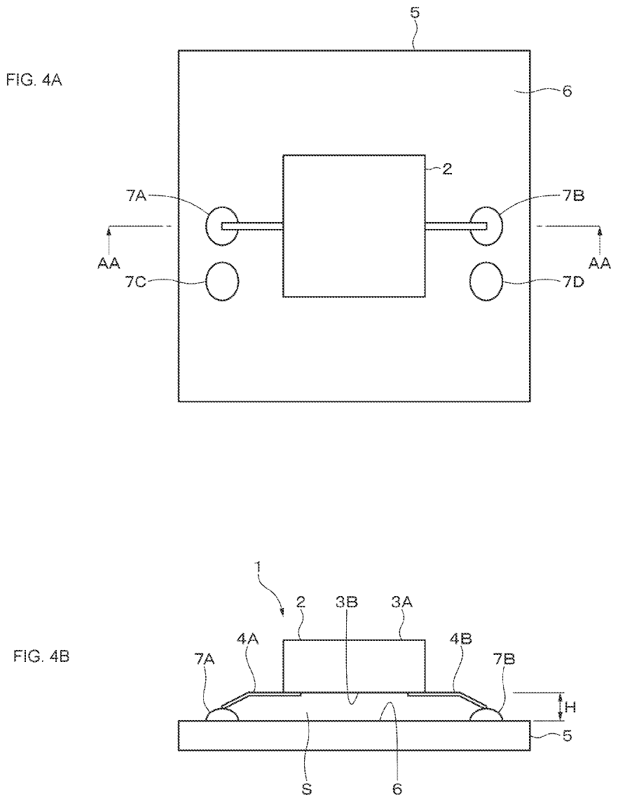

A substrate (substrate 5) according to this embodiment has a plate-like shape as a whole. FIG. 3 is a top view of the substrate 5. One main surface of the substrate 5 is a pad forming surface 6 on which a plurality of pads is formed. A plurality of pad is formed on the pad forming surface 6. For example, 4 pads (pads 7A, 7B, 7C, and 7D) are formed on the pad forming surface 6 of the substrate 5. The pad 7A and the pad 7C are formed at positions close to each other, and the pad 7B and the pad 7D are formed at positions close to each other.

Part A of FIG. 4 is a top view of a state where the chip part 1 is connected to the substrate 5, and Part B of FIG. 4 is a diagram showing the cross section in the case where the part including the chip part 1 and the substrate 5 is cut by a cutting line AA-AA. As shown in Part A of FIG. 4, and Part B of FIG. 4, for example, the vicinity of the tip of the wiring 4A is connected to the pad 7A, and the vicinity of the tip of the wiring 4B is connected to the pad 7B. The connection method may be, solder bonding, ultrasonic bonding, connection using a conductive adhesive, or the like, and is not limited. The chip part 1 and the substrate 5 in the connected state correspond to one aspect of an electronic part. While the wiring portion 4 is connected to a predetermined pad (in this example, the pads 7A and 7B), as shown in Part B of FIG. 4, a gap S having a certain height H or more is formed between the bottom surface 3B of the chip body portion 2 and the pad forming surface 6. That is, the chip body portion 2 is supported by the wiring portion 4 in a state of floating from the substrate 5.

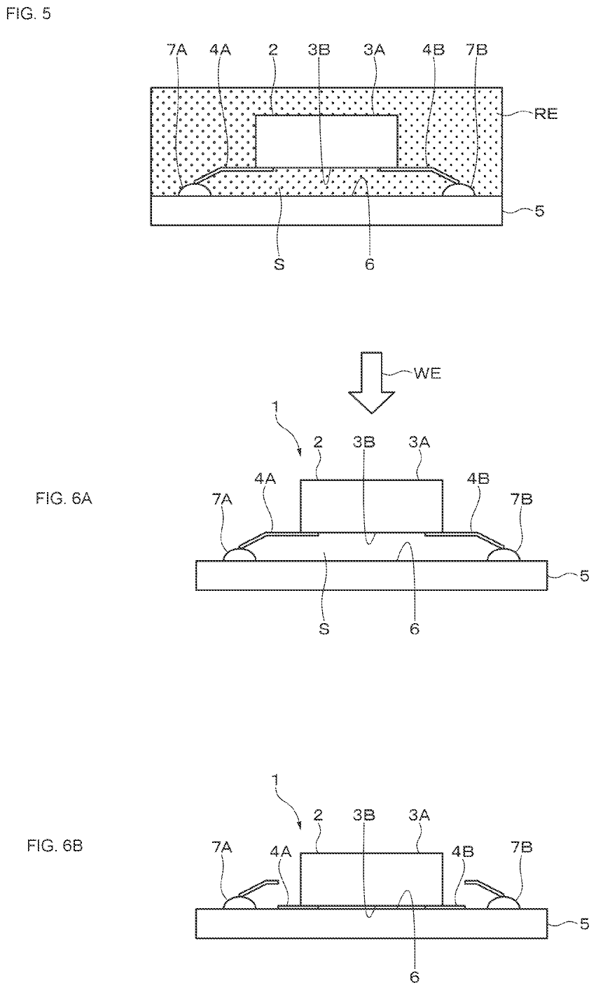

As will be described in detail below, the chip part 1 is energized in the state shown in Part B of FIG. 4 and an electrical inspection of the chip part 1 is performed. In the case where the result of the electrical inspection is OK, a resin RE is applied around the chip part 1 to seal the chip part 1 as schematically shown in FIG. 5. More specifically, the part including the wiring portion 4 and the gap S is sealed by the resin RE. Since also the gap S is filled with the resin RE, the chip part 1 can be fixed to the substrate 5 in a stable state.

[Processing Relating to Repair]

In the case where the above-mentioned result of the electrical inspection is NG, e.g., the chip part 1 is not energized and the chip part 1 does not emit light, processing relating to repair for removing the chip part 1 and reconnecting a new chip part 1 is performed.

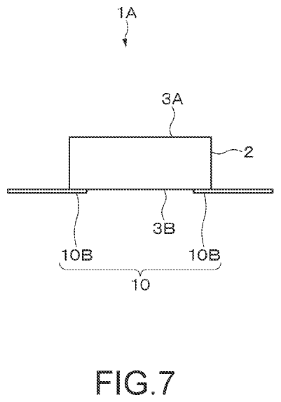

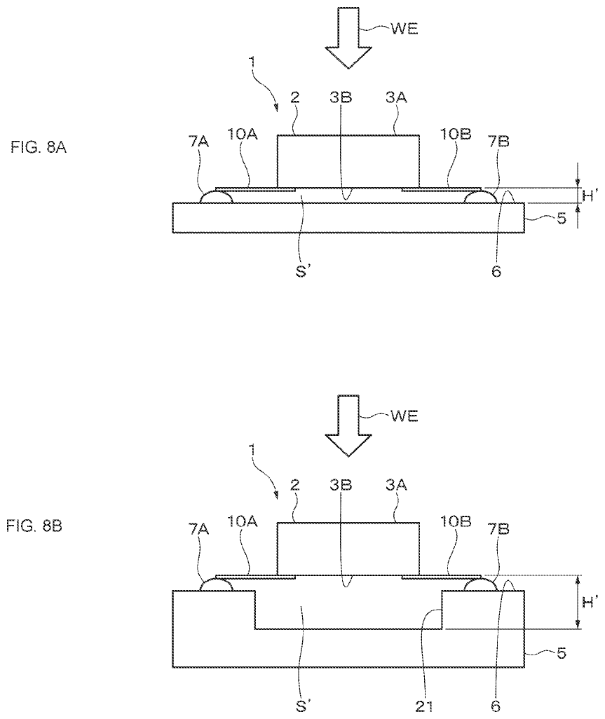

Part A of FIG. 6 and Part B of FIG. 6 are each a diagram describing processing of removing the chip part 1, which is performed in the processing relating to repair. In the case where the result of the electrical inspection is NG, since there is a high possibility the chip part 1 is defective, the chip part 1 is replaced. As shown in Part A of FIG. 6, for example, a downward weight (stress) WE is applied to the upper surface 3A of the chip body portion 2. When the weight WE is applied, the chip body portion 2 is displaced downward (direction toward the gap S), a weight is applied to the wiring 4A and the wiring 4B, and thus, the wiring 4A and the wiring 4B re cut as shown in Part B of FIG. 7. Since the wiring 4A and the wiring 4B are each in the form of a thin foil, they can be easily cut even with the slight weight WE. The application of the weight WE may be performed mechanically or manually. As described above, in the electronic part according to this embodiment, the wiring 4A connected to the pad 7A and the wiring 4B connected to the pad 7B can be cut by applying a weight to the upper surface 3A.

The chip part 1 in which the wiring 4A and the wiring 4B have been cut is removed from the substrate 5. Then, a newly prepared chip part 1 is connected to the substrate 5. At this time, since part of the wiring 4A remains on the pad 7A and part of the wiring 4B remains on the pad 7B as shown in Part B of FIG. 6, there is a possibility that it is difficult to connect the wiring portion 4 of the newly prepared chip part 1 to the pad 7A and the pad 7B. In this regard, it is favorable that the wiring 4A of the newly prepared chip part 1 is connected to, for example, the pad 7C and the wiring 4B of the newly prepared chip part 1 is connected to, for example, the pad 7D from the viewpoint of making favorable electrical connection. As described above, it is favorable that pads (4 in this example) whose number is even multiples of the number of wirings (2 in this example) are formed on the pad forming surface 6 considering that the result of the electrical test can be NG.

[Effects Obtained by this Embodiment]

In accordance with this embodiment, since the gap S is formed between the bottom surface 3B of the chip part 1 and the pad forming surface 6, it is possible to cut the wiring portion 4 by only applying the weight WE to the upper surface 3A of the chip part 1. Therefore, it is possible to easily remove the chip part 1.

Further, since the wiring portion 4 can be cut by only applying the slight weight WE, it is possible to cut the wiring portion 4 without a complicated process such as cutting using a laser or the like. It goes without saying that the wiring portion 4 may be cut using a laser or the like.

Further, since the bottom surface 3B of the chip part 1 is not fixed to the pad forming surface 6 of the substrate 5 at the stage of the electrical inspection, it is possible to remove the chip part 1 without damaging the substrate 5 even in the case where the result of the electrical inspection is NG and the chip part 1 is to be removed. Meanwhile, in the case where the result of the electrical inspection is OK, since also the gap S between the chip body portion 2 and the substrate 5 is filled with the resin RE, it is possible to stably fix the chip part 1 to the substrate 5.

Further, since the number of pads is set to even multiples of the number of wirings, it is possible to connect, at the time of repair, the wiring portion 4 of the new chip part 1 to the pad on which no wiring remains. As a result, it is possible to perform electrically stable connection.

Further, since it is unnecessary to apply heat when removing the chip part 1 from the substrate 5, the number of times of applying heat can be suppressed even in the case of using solder. Therefore, it is possible to minimize the damage to the substrate 5 due to heat.

Since the pads 7A to 7D are formed on the outside of the chip body portion 2, even in the case where a spare pad is to be provided, it is possible to easily provide a space for forming the pad.

### Second Embodiment

Subsequently, a second embodiment will be described. Note that the matters described in the first embodiment can be applied to the second embodiment unless otherwise specified. The same or similar configurations as those described in the first embodiment will be denoted by the same reference symbols, and overlapping description will be omitted as appropriate.

FIG. 7 is a side view of a chip part (chip part 1A) according to a second embodiment. The chip part 1A is different from the chip part 1 according to the first embodiment in that the shape of the wiring portion differs. That is, although the wiring portion 4 according to the first embodiment is bent downward from the middle thereof, a wiring portion (wiring portion 10) according to the second embodiment is not bent.

The wiring portion 10 includes a wiring 10A and a wiring 10B. As described above, the wiring 10A and the wiring 10B are not bent and extend in a direction substantially parallel to the bottom surface 3B.

Part A of FIG. 8 shows the state where the wiring 10A is connected to the pad 7A and the wiring 10B is connected to the pad 7B. In such a state, similarly to the first embodiment, a gap S′ is formed between the bottom surface 3B and the pad forming surface 6. However, since the wiring 10A and the wiring 10B are not bent, a height H′ of the gap S′ decreases. For this reason, a sufficient amount of displacement of the chip body portion 2 cannot be achieved even in the case where the weight WE is applied to the upper surface 3A at the time of repair. For this reason, there is a possibility that a sufficient weight is not applied to the wiring 10A and the wiring 10B and the wiring 10A and the wiring 10B cannot be cut.

In this regard, in this embodiment, a recessed portion 21 is formed on the pad forming surface 6 as shown in Part B of FIG. 8. By forming the recessed portion 21, it is possible to sufficiently increase the height H′ of the gap S′ and increase the amount of displacement of the chip body portion 2 in the case where the weight WE is applied to the upper surface 3A at the time of repair. For this reason, a sufficient weight can be applied to the wiring 10A and the wiring 10B, and thus, it is possible to easily cut the wiring 10A and the wiring 10B.

Although the shape and size of the recessed portion 21 can be set as appropriate, it is favorable that the recessed portion 21 is formed in a part of the pad forming surface 6 facing at least the bottom surface 3B from the viewpoint of achieving a sufficient amount of displacement of the chip body portion 2 as described above. The pad 7A and the pad 7B are formed on end surfaces of the portions projecting from the peripheral edge of the recessed portion 21.

In accordance with this embodiment described above, it is possible to sufficiently displace the chip body portion 2 even in the case where the wiring portion 10 is not bent or the wiring portion 10 is bent only slightly. Therefore, it is possible to easily remove the chip part 1A from the substrate 5, similarly to the first embodiment. Note that in the first embodiment, the recessed portion 21 may be formed on the substrate 5.

Note that the electronic part (e.g., the electronic part shown in FIG. 5) described in the first and second embodiments is applicable as, for example, a one-pixel configuration in a large-sized display. That is, by using a large number of electronic parts for unitizing, it is possible to configure a large-sized display (referred to also as a crystal display or the like) using an LED.

### Modified Example

Although a plurality of embodiments of the present disclosure has been specifically described above, the content of the present disclosure is not limited to the above-mentioned embodiments and various modifications based on the technical idea of the present disclosure can be made.

Although the configuration in which the wiring portion includes two wirings has been described in the above-mentioned embodiments, the wiring portion may include other numbers of wirings. For example, the wiring portion may include 4 wirings. Of the 4 wirings, 3 wirings are wirings corresponding to the anode side or cathode side of RGB, and the 1 wiring is a common wiring on the anode side or cathode side. In this case, as shown in Part A of FIG. 9, 4 wirings (wirings 14A, 14B, 14C, and 14D) may be pulled out from the cross direction of the chip body portion 2. Then, as shown in Part B of FIG. 9, the tip of the wiring 14A is connected to a pad 15A, the tip of the wiring 14B is connected to a pad 15B, the tip of the wiring 14C is connected to a pad 15C, and the tip of the wiring 14D is connected to a pad 15D.

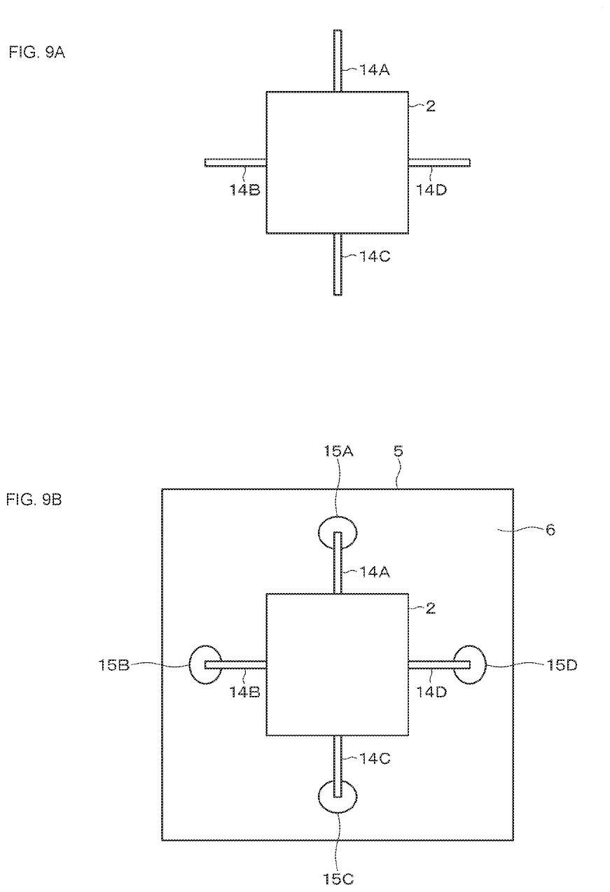

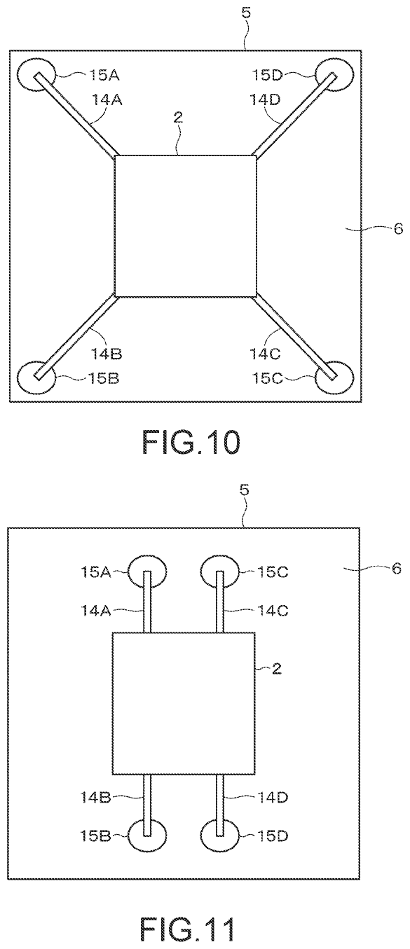

Further, the 4 wirings may be derived from not the cross direction but the vicinity of each corner of the chip body portion 2 as shown in FIG. 10. Then, the tips of the wirings may be connected to the pad 15A to 15D formed in the vicinity of the respective corners of the substrate 5. Further, of the 4 wirings, two wirings may be derived from the same direction of the chip body portion 2. For example, as shown in FIG. 11, the wiring 14A and the wiring 14C may be derived from the same direction of the chip body portion 2, and the wiring 14B and the wiring 14D may be derived from the same direction of the chip body portion 2.

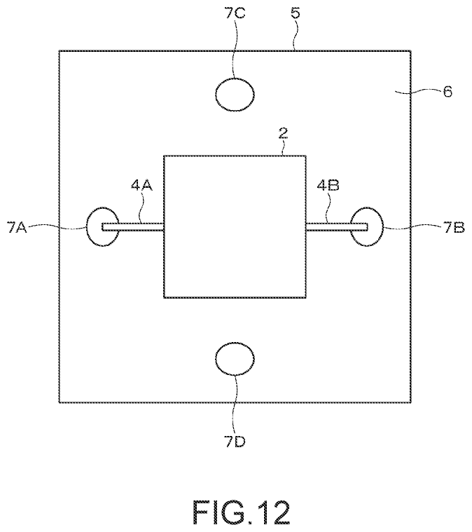

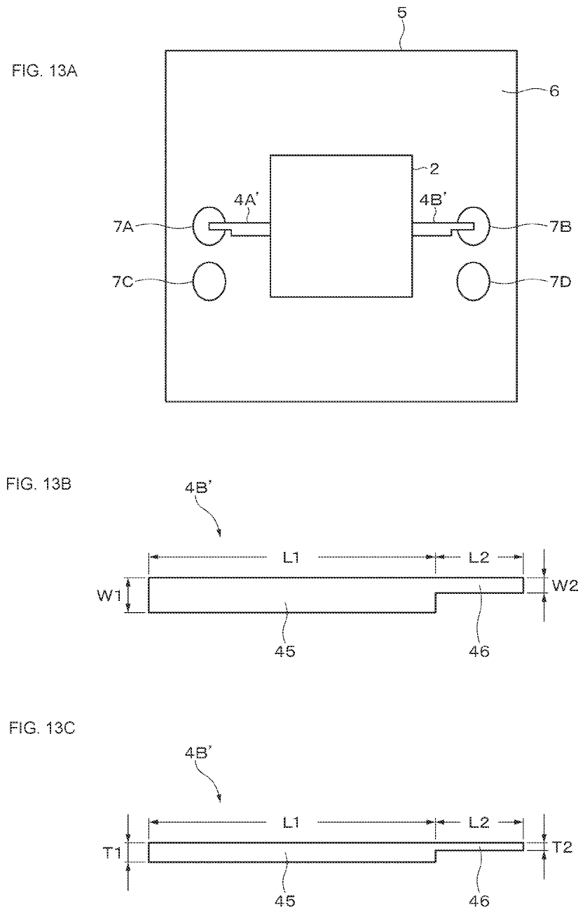

In the above-mentioned embodiments, the spare pad 7C used at the time of repair may be formed not in the vicinity of the pad 7A but at a position separated from the pad 7A by a predetermined distance or more. As shown in FIG. 12, the same applied also to the pad 7D.

A structure that is mechanically vulnerable to the application of a weight may be formed in a wiring of a wiring portion. As shown in Part A of FIG. 13, a wiring 4A′ and a wiring 4B′ according to a modified example are derived from the chip part 1 (specifically, the chip body portion 2). As shown in Part B of FIG. 13, for example, the wiring 4B′ according to the modified example has a configuration in which a first wiring 45 derived from the chip body portion 2 and a second wiring 46 that extends from the tip of the first wiring 45 and has the tip to be connected to the pad 7B are formed in a continuous manner.

The length of the first wiring 45 is a length L1, and the length of the second wiring 46 is a length L2 (see Part B of FIG. 13). The width of the first wiring 45 is a width W1, and the width of the second wiring 46 is a width W2 (see Part B of FIG. 13). The thickness of the first wiring 45 is a thickness T1, and the thickness of the second wiring 46 is a thickness T2 (see Part C of FIG. 13). At least one of the width W2 and the thickness T2 of the second wiring 46 is set to be smaller than at least one of the width W1 and the thickness T1 of the first wiring 45. In this example, the width W2 of the second wiring 46 is set to be smaller than the width W1 of the first wiring 45, and the thickness T2 of the second wiring 46 is set to be smaller than the thickness T1 of the first wiring 45 (see Part B of FIG. 13 and Part C of FIG. 13). One of the width W2 and the thickness T2 of the second wiring 46 may be set to be smaller than one of the width W1 and the thickness T1 of the first wiring 45.

As a result, in the case where the weight WE is applied to the chip part 1, the wiring can be easily cut at the part of the second wiring 46. Therefore, it is possible to further decrease the weight WE to be applied. Note that since the second wiring 46 remains when repair is performed, the length L2 of the second wiring 46 is favorably smaller than the length L1 of the first wiring 45. As a result, it is possible to make the remaining wiring smaller. Therefore, it is possible to prevent the chip part and the like from being damaged by the remaining wiring. Further, although the case where a structure that is mechanically vulnerable to the application of the weight WE is formed in the wiring 4B′ has been described in the above-mentioned example, a structure mechanically vulnerable to the application of the weight WE may be formed in the wiring 4A′ as shown in Part A of FIG. 13.

In the above-mentioned embodiments, in the case where the chip body portion cannot be supported by the wiring portion, a member that assists the support of the chip body portion and deforms by the application of a weight may be disposed in the gap S. Examples of such a member include an elastically deformed body such as sponge and rubber. Such an elastically deformed body does not necessarily need to be disposed in the entire gap S and may be locally disposed in the space of the gap S.

The chip part can be applied also to a chip part other than those including a light-emitting element. Further, the substrate may be supported in the horizontal direction or in the vertical direction. The present disclosure can be configured also as a production device or an inspection device for executing the process according to the embodiment.

The configurations, methods, processes, shapes, materials, numerical values, and the like given in the above-mentioned embodiments and modified example are merely examples and may be replaced with known ones, and configurations, methods, processes, shapes, materials, numerical values, and the like different from these may be used as necessary. Further, the configurations, methods, processes, shapes, materials, numerical values, and the like in the embodiments and modified example can be combined with each other as long as there is no technical contradiction.

It should be noted that the content of the present disclosure is not limitedly interpreted by the effects illustrated in the present specification.

The present disclosure may also take the following configurations.

(1) An electronic part, including:

a chip part having a first main surface and a second main surface opposite to the first main surface, a wiring portion being derived from the chip part; and

a substrate having a pad forming surface, pads to which the wiring portion can be connected being formed on the pad forming surface, in which

a gap is formed between the second main surface and the pad forming surface while the wiring portion is connected to a predetermined pad of the pads.

(2) The electronic part according to (1), in which

the wiring portion connected to the pad can be cut by applying a weight to the first main surface.

(3) The electronic part according to (1) or (2), in which

a part including the wiring portion connected to the pad and the gap are sealed with a resin.

(4) The electronic part according to any one of (1) to (3), in which

a recessed portion is formed in a part of the pad forming surface facing at least the second main surface.

(5) The electronic part according to any one of (1) to (4), in which

the wiring portion includes a plurality of wirings.

(6) The electronic part according to (5), in which

the wiring portion includes two or four wirings.

(7) The electronic part according to (5) or (6), in which

each of the wirings has a configuration in which a first wiring derived from the chip part and a second wiring that extends from a tip of the first wiring and has a tip to be connected to the pad are formed in a continuous manner, and

at least one of a width or a thickness of the second wiring is set to be smaller than at least one of a width or a thickness of the first wiring.

(8) The electronic part according to (7), in which

a length of the second wiring is set to be smaller than a length of the first wiring.

(9) The electronic part according to any one of (5) to (8), in which

the number of the pads is even multiples of the number of wirings of the wiring portion.

(10) The electronic part according to any one of (1) to (9), in which

the chip part includes a light-emitting element.

(11) A method of producing an electronic part, including:

connecting a wiring portion to a predetermined pad formed on a pad forming surface of a substrate, the wiring portion being derived from a chip part having a first main surface and a second main surface opposite to the first main surface;

performing an electrical inspection while the wiring portion is connected to the pad; and

sealing, where a result of the inspection is OK, a part including the chip part and the wiring portion with a resin, and cutting, where a result of the inspection is NG, the wiring portion by applying a weight to the first main surface of the chip part.

### REFERENCE SIGNS LIST

1 chip part
2 chip body portion
3A upper surface
3B bottom surface
4 wiring portion
4A,4B wiring
5 substrate
6 pad forming surface
7A to 7D pad
S gap
L length of wiring
W width of wiring
T thickness of wiring
WE weight
RE resin

1. An electronic part, comprising:
a chip part having a first main surface and a second main surface opposite to the first main surface, a wiring portion being derived from the chip part; and
a substrate having a pad forming surface, pads to which the wiring portion can be connected being formed on the pad forming surface, wherein
a gap is formed between the second main surface and the pad forming surface while the wiring portion is connected to a predetermined pad of the pads.

2. The electronic part according to claim 1, wherein
the wiring portion connected to the pad can be cut by applying a weight to the first main surface.

3. The electronic part according to claim 1, wherein
a part including the wiring portion connected to the pad and the gap are sealed with a resin.

4. The electronic part according to claim 1, wherein
a recessed portion is formed in a part of the pad forming surface facing at least the second main surface.

5. The electronic part according to claim 1, wherein
the wiring portion includes a plurality of wirings.

6. The electronic part according to claim 5, wherein
the wiring portion includes two or four wirings.

7. The electronic part according to claim 5, wherein
each of the wirings has a configuration in which a first wiring derived from the chip part and a second wiring that extends from a tip of the first wiring and has a tip to be connected to the pad are formed in a continuous manner, and
at least one of a width or a thickness of the second wiring is set to be smaller than at least one of a width or a thickness of the first wiring.

8. The electronic part according to claim 7, wherein
a length of the second wiring is set to be smaller than a length of the first wiring.

9. The electronic part according to claim 5, wherein
the number of the pads is even multiples of the number of wirings of the wiring portion.

10. The electronic part according to claim 1, wherein
the chip part includes a light-emitting element.

11. A method of producing an electronic part, comprising:
connecting a wiring portion to a predetermined pad formed on a pad forming surface of a substrate, the wiring portion being derived from a chip part having a first main surface and a second main surface opposite to the first main surface;
performing an electrical inspection while the wiring portion is connected to the pad; and
sealing, where a result of the inspection is OK, a part including the chip part and the wiring portion with a resin, and cutting, where a result of the inspection is NG, the wiring portion by applying a weight to the first main surface of the chip part.
